(19) United States
(12) Patent Application Publication
(10) Pub. No.: US 2026/0235221 A1
(43) Pub. Date: Aug. 13, 2026

(54) FLAP VALVE AND SEAL WITH IMPROVED SEAL GEOMETRY FOR SUCH A VALVE

(71) Applicant: VAT HOLDING AG, Haag (CH)

(72) Inventors: Christoph RUPP, Mels (CH); Karlheinz SUMMER, Bludenz (AT); Hanspeter FREHNER, Sevelen (CH); Martin NETZER, Bludenz (AT)

(21) Appl. No.: 19/151,271

(22) PCT Filed: Jan. 24, 2024
(86) PCT No.: PCT/EP2024/051678

§ 371 Date: Jul. 25, 2025

(30) Foreign Application Priority Data
Jan. 27, 2023 (DE) 10 2023 000 251.8

(51) Int. Cl. F16K 25/00; F16K 15/03; F16K 15/16; F16K 51/02

(52) U.S. Cl. CPC F16K 25/00; F16K 15/03; F16K 15/16; F16K 51/02

(57) ABSTRACT

A sealing element for a valve closure of a valve includes a fastening region with a fastening body and a sealing region for providing a seal for a valve opening of the valve, where the fastening region and the sealing region are connected to one another. The sealing element has a sealing lip and an aligning lip in the sealing region. The sealing lip and the aligning lip are aligned relative to one another such that they enclose an opening angle. The sealing lip is designed to provide the sealing of the valve opening of the valve and the aligning lip is designed to align the sealing region relative to a sealing surface when brought into contact with the sealing surface. The fastening body has at least one retaining surface on an underside opposite the sealing region.

The invention relates to a specific sealing element for a valve, a valve closure having such a sealing element and a valve, in particular having such a valve closure.

Valves are generally intended to adjust the flow through the valve, in particular the flow of a fluid. With a valve, the flow can be permitted in particular via a maximum valve opening cross-section or completely shut off. In addition, certain valve types offer the option of regulating a flow rate per unit of time, Le, provide the ability to regulate a fluid flow.

Vacuum valves are a specific type of valve. These are known from the prior art in various designs for regulating a volume or mass flow and/or for essentially gas-tight closure of a flow path that leads through an opening formed in a valve housing and are used in particular in vacuum chamber systems in the field of IC, semiconductor or substrate production, which must take place in a protected atmosphere, preferably without the presence of contaminating particles.

Such vacuum chamber systems comprise, in particular, at least one evacuable vacuum chamber provided for holding semiconductor elements or substrates to be processed or manufactured, which has at least one vacuum chamber opening through which the semiconductor elements or other substrates can be guided into and out of the vacuum chamber, and at least one vacuum pump for evacuating the vacuum chamber. For example, in a production system for semiconductor wafers or liquid crystal substrates, the highly sensitive semiconductor or liquid crystal elements pass sequentially through several process vacuum chambers in which the parts located within the process vacuum chambers are each processed by means of a processing device. Both during the processing process within the process vacuum chambers and during transportation from chamber to chamber, the highly sensitive semiconductor elements or substrates must always be in a protected atmosphere in particular in an airless environment.

Peripheral valves are used to open and close a gas inlet or outlet and transfer valves are used to open and close the transfer openings of the vacuum chambers for inserting and removing the parts, Peripheral valves are used in particular to control or regulate a gas flow between a vacuum chamber and a vacuum pump or another vacuum chamber.

The process chambers are connected to each other via transfer channels, for example. These process chambers can be opened using vacuum transfer valves to transfer the parts from one process chamber to the next and then closed gas-tight to carry out the respective production step, In addition, movable transfer chambers are used which dock onto the process chambers and can transport the semiconductor elements between the process chambers in a protective atmosphere.

From the prior art, for example U.S. Pat. Nos. 5,076,205 or 5,292,393, multi-chamber systems for the manufacture of semiconductor elements—in particular semiconductor wafers—are known, in which a plurality of process chambers are arranged in a star shape around a central transfer chamber. The central transfer chamber is connected via a tunnel to a second transfer chamber, around which further process chambers are arranged in a star shape, so that a large coherent semiconductor manufacturing system can be produced by means of a large number of such processing islands. The semiconductor elements are transported from one process chamber via the transfer chamber to the next process chamber by a handling system arranged in the transfer chamber,

It is also possible to arrange the process chambers sequentially in a chain of process chambers, wherein a connecting opening is provided between the adjacent process chambers, which can be closed in a gas-tight manner by means of a transfer valve. In this case, each process chamber has at least two openings, with the outlet opening of a process chamber being the inlet opening of a subsequent process chamber in the process chamber chain. A transfer valve is located between each two process chambers and at the beginning and end of the process chamber chain, each of which has two valve openings in its valve housing that can be separated from each other in a gas-tight manner.

The vacuum chamber systems described are used for different areas of semiconductor and substrate production and have proven themselves for the production and processing of small to medium-sized semiconductor and substrate components. However, new technical areas require ever larger integral semiconductor components and substrates that require the creation of new production systems. Examples of this are solar panels or screen panels, in particular plasma and LCD panels, with a width of over one meter, To process such large semiconductor components, liquid crystal substrates or other substrates, correspondingly large process chambers and transfer valves are required.

In materials science, a substrate is generally understood to be a material to be treated, wherein in particular the surface of the substrate is refined or coated. This may be a wafer from the field of semiconductor technology, a base material of a printed circuit board or any other material, in particular plate-like or strip-like material, which is processed accordingly by means of a coating, finishing or treatment process that must take place in a vacuum or in a process gas environment. A substrate is also to be understood as a glass plate to be coated, for example for a flat screen or a solar panel with a thickness of less than 0.5 to more than 5 millimeters, or a stainless steel foll or a stainless steel strip with a thickness of less than 0.05 to more than 0.2 millimeters.

Such transfer valves for opening and closing process chambers are therefore characterized by extremely large dimensions, a long seal length and a very large opening cross-section, sometimes with a width of over 1500 millimeters, depending on the process in question. The opening cross-sections are particularly elongated and slot-like, with the width being significantly greater than the height of the opening. Due to the described area of application and the associated dimensions, these valves are referred to as transfer valves, due to their rectangular opening cross-section also as rectangular valves and, depending on their mode of operation, also as slide valves, rectangular slide valves, transfer slide valves, flap valves, flap transfer valves or rotary valves.

U.S. Pat. No. 6,416,037 (Geiser) or U.S. Pat. No. 6,056,266 (Blecha) describe small transfer valves in the form of vacuum slide valves or slide valves, also known as valve slides or rectangular slide valves. In the prior art, closing and opening usually takes place in two steps. In a first step, a valve closure, in particular a closure disk, is moved linearly over an opening essentially parallel to the valve seat without any contact taking place between the valve closure and the valve seat of the valve housing, In a second step, the valve closure is pressed with its closure side onto the valve seat of the valve housing so that the opening is closed in a gas-tight manner.

Smaller slide valves are also known, in which the closing and sealing process takes place via a single linear movement. Such a valve is, for example, the transfer valve known under the product name “MONOVAT Series 02 and 03” and designed as a rectangular insert valve from VAT Vakuumventile AG in Haag, Switzerland. The design and function of such a valve are described, for example, in U.S. Pat. No. 4,809,950 (Geiser) and U.S. Pat. No. 4,881,717 (Geiser).

Such drive technologies have proven themselves in the prior art, but they are only suitable to a limited extent for very large opening cross-sections, especially elongated, slot-like opening cross-sections.

Due to the long seal lengths resulting from the large opening cross-section, the demands on the seals, the valve closure guide and the actuator are very high.

Various sealing devices for this purpose are known from the prior art, for example from U.S. Pat. No. 6,629,682 B2 (Duelli). A suitable material for sealing rings and seals in vacuum valves is, for example, fluororubber, also known as FKM, in particular the fluoroelastomer known under the trade name “Viton”, as well as perfluororubber, FFKM for short.

With such large seal lengths and opening cross-sections, a particular challenge is to ensure tightness over the entire seal length, even with very large pressure differences, and thus a certain contact pressure between the valve closure and valve seat.

Maintaining a constant contact pressure with large pressure differences can be problematic, especially with large valves. In order to maintain a constant contact pressure, certain transfer valves provide for a particularly robust dimensioning of the valve closure and its drive as well as its bearing, so that the valve closure retains its set position even with high forces acting on the valve closure due to the pressure difference and does not change its position unintentionally. A flap valve is known from EP 2 355 132 B1 , which represents a solution to this problem, wherein a contact pressure that is as constant as possible can be provided along the entire sealing length of the seal of a valve.

Due to their robustness and wall thickness, such valves typically have comparatively large installation dimensions. This is particularly disadvantageous in terms of the space required for installation, but also for parts handling. On the one hand, a reduction in the installation dimension appears limited due to the given spatial expansion of the valve closure, In addition, to provide the required contact pressure, a correspondingly robust drive mechanism, which in turn requires a large wall thickness for support, is prior art.

The invention is therefore based on the object of providing an improved valve, in particular a vacuum valve, which reduces or avoids the above-mentioned disadvantages.

The present invention is based in particular on the object of designing a valve, which in particular has an elongated, in particular slot-like first opening, in such a way that when the seal is pressed onto the valve seat, tightness can be reliably ensured and the formation of particles can be avoided, wherein the valve provides an improved installation dimension with an essentially constant characteristic.

It is also a further object of the invention to provide an improved valve closure or an improved sealing element for such a valve, which contributes to solving the object.

These objects are solved by the realization of the characterizing features of the independent claims. Features which further develop the invention in an alternative or advantageous manner can be found in the dependent claims.

The basic idea of the present invention is to provide a valve, in particular a vacuum valve, whose valve housing has two opposing valve openings and a valve closure with a seal (sealing element) for closing a first of these openings. In a closed position, the valve closure covers this first valve opening, wherein the seal rests against the valve seat of the first valve opening and thus closes the first valve opening (gas-tight). The dimensioning of the valve housing is such that the valve closure is at least partially present in the opposite, second valve opening in an open position, in which the valve closure releases the first valve opening to the maximum.

This constructive design means that it is no longer necessary for the first and second valve openings to be so far apart that the valve closure can be placed completely between these openings in the open position; instead, the dimensions of the valve, in particular the valve housing, can be significantly reduced. In particular, it is possible to reduce the installation width by at least that part of the length of the valve closure which projects into the second valve opening in the open position.

To further reduce the size, an alternative flap drive is also proposed, which on the one hand requires less space but on the other hand is able to apply reduced contact pressure. The contact pressure that can be generated to press the valve closure against the valve seat can be sufficient for typical vacuum applications.

However, specific vacuum applications, for example with comparatively large pressure differences, can place increased demands on the tightness of the system. In this context, an improved sealing element and an improved valve closure having such a sealing element are proposed according to the invention, which can be combined with a valve according to the invention to achieve a further improved sealing effect.

The proposed design of the sealing element (seal) according to the invention provides a reliable alignment of the sealing element on the one hand relative to the valve closure and on the other hand relative to the valve seat when closing the valve. For this purpose, the sealing element has a sealing region with two sealing lips that are arranged and aligned in a Y-shape, One of the sealing lips provides the desired sealing effect, the second lip serves to maintain the desired alignment of the sealing region, and thus of the sealing lip provided for the sealing effect, relative to the valve seat even in the event of non-orthogonal (oblique) contact with the valve seat.

The second lip, hereinafter also referred to as the aligning lip, can in particular also have venting passages, e.g. material recesses in the course of the lip, which ensure that an intermediate space between the lips and the valve seat can be vented when contact is made with the valve seat and that no undesired air pockets remain. Such air pockets can result in an uncontrolled, delayed outflow of a fluid that is undesirable for a processing process (e.g. gas) and thus make the process unstable. The aligning lip is therefore arranged on the inside of a sealing element (surrounding the valve closure in the edge area), i.e. when the valve opening is closed in the direction of this opening.

To reliably provide the desired alignment of the sealing element relative to the valve closure, the sealing element has a fastening body whose underside, which is diametrically aligned with the sealing region, is flat. This provides a contact surface by means of which the sealing element can assume the preferred alignment when interacting with a corresponding surface of the valve closure or the valve seat.

The invention thus relates to a sealing element for a valve closure and/or valve seat of a valve, in particular a vacuum valve, The sealing element has, on the one hand, a fastening region with a fastening body, which is designed for fastening the sealing element to the valve closure and/or valve seat, and, on the other hand, a sealing region for providing a seal for a valve opening of the valve. The fastening region and the sealing region are connected to each other or are designed to be contiguous.

The sealing element has a sealing lip and an aligning lip in the sealing region, wherein the sealing lip and the aligning lip are aligned relative to each other in such a way that they enclose an opening angle a. The sealing lip is designed to provide the sealing of the valve opening of the valve and the aligning lip is designed to align the sealing region relative to a sealing surface when brought into contact with this surface. The fastening body has a retaining surface on an underside opposite the sealing region.

The underside can generally be understood here as a side of the sealing element that faces the sealing region and is associated with the fastening region. However, the underside is not necessarily to be understood as a side that faces away from the sealing region. Rather, the underside should be understood as a side relating to the lower part of the sealing element, wherein the sealing region is associated with the upper part of the sealing element.

In one embodiment, the retaining surface can be aligned parallel to a transvers axis, wherein the transverse axis is oriented orthogonally to a contact pressure direction defined by the opening angle, in particular wherein the retaining surface is of flat design.

The retaining surface can therefore form a flat bottom side of the sealing element and thus a corresponding contact surface for interaction with a corresponding mating surface.

Alternatively, the retaining surface can be aligned transversely to the transverse axis.

Furthermore, the sealing element can have a further retaining surface or several further retaining surfaces, which are designed to maintain a desired alignment of the sealing element. In particular, a valve closure on which the sealing element is to be arranged can have corresponding elements (surfaces) that interact with the retaining surfaces when the sealing element is connected to the closure. The retaining surfaces can, for example, be arranged at an angle to one another, e.g. describe a V-shape, an L-shape or a U-shape, or be aligned parallel to one another.

In one embodiment, the fastening body can be comparatively thin. The thickness of the fastening body can be small relative to the opposite extension of the sealing region. Such an embodiment can provide the requirements on the fastening body side for vulcanizing the sealing element to the valve closure or valve seat. The fastening body is to be understood here in particular as a section or part of the sealing element that provides the connection of the sealing element to a carrier surface (sealing surface) by means of vulcanization.

In one embodiment, the relative orientation of the sealing lip and the aligning lip can be Y-shaped.

In one embodiment, the sealing lip and the aligning lip can enclose an opening angle a from a range between 90° and 160°, in particular an angle from a range of 110° to 150°.

Such a relative alignment allows the aligning lip in particular to contribute to the sealing lip also contacting the sealing surface when it comes into contact with a sealing surface of a valve seat without the sealing lip also already contacting the sealing surface. In this case, the sealing region (relative to the fastening region), i.e. the sealing lip and the aligning lip, can be pivoted towards the sealing surface, in particular so that the contact pressure direction is aligned orthogonally to the sealing surface.

The sealing lip and the aligning lip are preferably designed, in particular with regard to this context, in such a way that the relative alignment of the lips is essentially maintained even if only one of the lips is rotated or pivoted, in particular at least as long as the sealing region is not pressed against a sealing surface.

In one embodiment, the fastening body can have a retaining element, wherein the retaining element provides the retaining surface (or a plurality thereof). In particular, the retaining element can be aligned in the opposite direction relative to the contact pressure direction A, in particular where the retaining element is designed as a pin, web, wedge or mandrel.

In one embodiment, the sealing element can have a longitudinal extension, in particular wherein the longitudinal extension extends in a direction orthogonally to the transverse axis and orthogonally to the contact pressure direction.

In particular, the sealing element can be designed as a closed sealing element, especially as a circumferential seal or as a ring (sealing ring) with a corresponding sealing profile.

In one embodiment, the aligning lip can have at least one recess, in particular a plurality of recesses, wherein the at least one recess is designed in such a way that an intermediate space, which is created between the sealing surface, the sealing lip and the aligning lip when the sealing region is brought into contact with the sealing surface, remains accessible through the at least one recess.

In particular, the at least one recess can be shaped as a notch, slot, perforation or hole.

In particular, the recess can act as a venting passage. When contact is made with a corresponding sealing surface (e.g. on the valve seat), a gap between the lips and the sealing surface can be vented by means of the recess. This means that no unwanted air pockets remain in the gap when the valve closes.

The recess can also provide ventilation of the intermediate space. The lips of the sealing element are typically clamped between the carrier body (valve closure) and the mating body (valve seat) in the evacuated state of a chamber. This prevents contact between the two bodies. With this type of compression, (any) fluid can also be pressed out of the space between the seal and, for example, the valve seat. When the valve is opened, this could result in a suction cup effect and the sealing element could remain sucked onto the valve seat. The recess can therefore ensure that the gap can be ventilated when the valve is opened and that the sealing element is not sucked onto the counter body (valve seat) (suction cup).

The profile seal (sealing element) can be of comparatively soft design due to its cross-section. The force required for the desired compression can therefore be significantly reduced.

The invention also relates to a valve closure, in particular a valve disk, for a valve, in particular a vacuum valve, for regulating a volume or mass flow and/or for closing and opening a valve opening, The valve closure has a coupling side having a coupling which is designed for coupling to a drive unit of the valve, In addition, a closing side is provided on the rear side relative to the coupling side with a seal that corresponds to a sealing surface of a valve seat of the valve. The closing side is therefore opposite the coupling side and faces in the opposite direction.

The valve closure has a retaining region on the closing side. The seal is designed as a sealing element as described above and the fastening body of the fastening region is connected to the retaining region.

In one embodiment, the fastening body of the fastening region can be connected to the retaining region by means of vulcanization, in particular vulcanized to this retaining region.

In one embodiment, the valve closure can have a groove on the closing side. The seal is designed as a sealing element as described above and the fastening body of the fastening region is located in the groove.

In one embodiment, the groove can be formed circumferentially in an edge area of the valve closure. The groove can therefore provide a recess on the closing side of the valve closure, which extends along a line along which the sealing effect of the closure is to be provided. This sealing line is preferably adapted to the course of a sealing surface on the side of the valve seat.

In one embodiment, the groove can have a groove bottom surface which is designed to correspond to the retaining surface of the fastening body. The groove bottom surface can be aligned correspondingly parallel or transverse to a surface of the closing side. In particular, the groove can have several bottom surfaces that correspond in particular with the arrangement of corresponding retaining surfaces of the fastening body.

The bottom of the groove can be understood in particular as the underside of the groove, which is opposite the groove opening.

According to one embodiment, the groove can have a trapezoidal cross-section, wherein the groove bottom surface is aligned parallel to a surface of the closing side.

Alternatively, the groove can have a different cross-section t corresponds to the cross-section of the fastening body or at least provides a desired arrangement and orientation of the fastening body relative to the groove or relative to the valve closure.

In one embodiment, the retaining surface of the fastening body can rest against the groove bottom surface accordingly. This interaction provides a desired and, in particular, permanent alignment of the seal relative to the valve closure,

According to one embodiment, a groove opening of the groove can have a width which is smaller than a width of the fastening body, in particular wherein the groove opening is opposite the groove bottom surface.

Accordingly, the invention relates to a valve, in particular a vacuum valve, for regulating a volume or mass flow and/or for closing and opening a valve opening.

The valve has a valve seat which has the valve opening defining an opening axis and a first sealing surface surrounding the valve opening, Furthermore, a valve closure, in particular a valve disk, is provided for regulating the volume or mass flow and/or for substantially gas-tight closure of the valve opening with a second sealing surface corresponding to the first sealing surface.

The valve also has a drive unit coupled to the valve closure, which is adapted to provide a movement of the valve closure in such a way that the valve closure can be moved from an open position, in which the valve closure at least partially releases the valve opening, into a closed position, in which there is sealing contact between the first sealing surface and the second sealing surface by means of a seal present therebetween and the valve opening is thereby closed in a gas-tight manner, and is adjustable back again.

The valve has a sealing element as described above and the sealing element provides the seal.

The sealing element can, for example, be arranged on the valve seat or on the valve closure or on both sides.

In one embodiment, the valve closure can be designed as described above and the second sealing surface can provide the retaining region, i.e. a groove is provided and the fastening body of the sealing element is located in the groove, and the sealing element provides or embodies the seal.

In one embodiment, the first sealing surface (on the valve seat) can have the sealing element.

In one embodiment, the first sealing surface can have a corresponding retaining region and the fastening body of the fastening region can be connected to the retaining region, in particular wherein the fastening body of the fastening region is connected to the retaining region by means of vulcanization, in particular is vulcanized on, or the retaining region of the first sealing surface has a groove and the fastening body of the fastening region is located in the groove.

In particular, the valve can be designed as a vacuum valve, wherein the valve closure can be tilted about an axis of rotation to enable the valve to be opened or closed.

The invention also relates to a valve, in particular a vacuum valve, for regulating a volume or mass flow and/or for closing and opening a first valve opening, The valve has a valve housing with the first valve opening and an opposing second valve opening, wherein the first valve opening defines an opening axis and the opening axis extends through the first and second valve openings. The valve has a valve seat that extends around the first valve opening and has a first sealing surface that extends around the first valve opening. The valve also has a valve closure, in particular a valve disk, for regulating the volume or mass flow and/or for essentially gas-tight closure of the valve opening.

Furthermore, the valve has a drive unit coupled to the valve closure, which is adapted to provide a folding movement of the valve closure about an axis of rotation oriented orthogonally relative to the opening axis in such a way that the valve closure can be adjusted from an open position, in which the valve closure releases the first valve opening to the maximum, into a closed position, in which there is a sealing contact between the valve closure and the valve seat and the first valve opening is thereby closed in a gas-tight manner, and back.

In the context of the invention, the maximum release of the first valve opening is to be understood in particular as a provided total opening cross-section of the valve, which corresponds at least to the cross-section of the first valve opening. A projection of the total opening cross-section provided extends in particular through the first valve opening and also through the second valve opening.

In the open position, at least part of the valve closure protrudes into the second valve opening. In particular, part of the valve closure is located in a passage or through-flow region defined by this opening.

In one embodiment, the second valve opening may define a second cross-sectional region that is larger than a first cross-sectional region of the first valve opening, in particular wherein the first and second cross-sectional regions are oriented orthogonally to the opening axis. In other words, the second valve opening is larger than the first valve opening. This size ratio may be due in particular to the fact that, in the open position, part of the valve closure is located in the second opening and this second opening must therefore provide an additional storage space for this part of the valve closure.

In particular, the second valve opening can have different cross-sectional sizes, wherein, for example, a cross-section of an inward-facing opening part (facing the first valve opening) is larger than a cross-section of an outward-facing opening part. The opening can, for example, have a step for this purpose, wherein the inner opening part is designed to receive or support the valve closure in the open position.

In one embodiment, the second valve opening can have a through-flow region provided by the valve housing, in particular by a thickness of the housing wall, in the direction of the opening axis, and the valve closure is at least partially present in the through-flow region in the open position.

In one embodiment, the first valve opening, the second valve opening and the valve closure can each have a longitudinal extension and a transverse extension, wherein the respective transverse extension is smaller than the respective longitudinal extension, The first valve opening, the second valve opening and the valve closure can thus be designed as elongated (rectangular) valve components with corresponding cross-sections.

In particular, the longitudinal extension and the transverse extension of the first valve opening can be oriented orthogonally to the opening axis and orthogonally relative to each other. The longitudinal extension and the transverse extension of the valve closure can-in the closed position-be oriented orthogonally to the opening axis and orthogonally relative to each other.

In one embodiment, a distance between the first valve opening and the second valve opening can be smaller than a spatial extension of the valve closure corresponding to its transverse extension (in the direction of the transverse extension), in particular wherein the distance between the first valve opening and the second valve opening is defined by an inner wall of the valve housing bounding the valve openings.

In one embodiment, the longitudinal extension of the first valve opening may be smaller than the longitudinal extension of the valve closure and/or the longitudinal extension of the second valve opening may be greater than the longitudinal extension of the valve closure, The longitudinal extension here is to be understood as a width of the valve opening(s) and of the valve closure in a frontal view of the valve.

In one embodiment, the valve closure can have a coupling side with a coupling for coupling to the drive unit. The drive unit can have an arm which can be pivoted about the axis of rotation by means of the drive unit and the arm can be coupled to the coupling.

It is understood that the valve closure can be designed in particular according to one of the embodiments described above.

In one embodiment, the first sealing surface, i.e. the valve seat, may have a sealing element as described above.

In one embodiment, the first sealing surface can have a retaining region and the fastening body of the fastening region can be connected to the retaining region, in particular wherein the fastening body of the fastening region is connected to the retaining region by means of vulcanization, in particular is vulcanized on, or the retaining region of the first sealing surface has a groove and the fastening body of the fastening region is located in the groove.

It is understood in principle that an arrangement of the sealing element on a valve seat can be designed analogously to an embodiment of the valve closure described above with such a sealing element.

In one embodiment, the valve can have a separating device for separating a process atmosphere region from an external atmosphere region. In particular, this relates to a design of the valve as a vacuum valve.

The process atmosphere region is to be understood in particular as a region that can be defined by a process chamber. In this region, a process atmosphere, in particular a vacuum, can be produced for processing substrates, Components intended for this area must meet increased requirements, e.g. with regard to material resistance. Accordingly, the external atmosphere region is to be understood in particular as an area in which normal atmospheric conditions are present, e.g. room air.

The drive unit can be assigned at least partially, in particular completely, to the external atmosphere region (e.g. a motor or a pneumatic system) and the valve closure, in particular, to the process atmosphere region.

The separating device of the valve can be formed by a bellows, for example, The bellows can be provided inside the valve housing or the drive unit, for example.

A valve known from the prior art and described, for example, in U.S. Pat. No. 6,772,989 has a valve body with two connections, a valve seat arranged in a flow path connecting the two connections in the flow chamber and an opening opposite the valve seat. A piston of a pneumatic cylinder system is arranged in a valve cover closing the opening, which drives a valve disk that opens and closes the valve seat via a valve rod. The valve cover is attached to the opening in a gas-tight manner by a bellows plate. The two ends of a bellows, which surrounds the valve rod, are attached gas-tight to the inner edge surface of the bellows plate and to the valve disk. On the surface facing the valve seat, the valve disk has an annular retaining groove in which a sealing ring is arranged.

A valve body is made of aluminum or stainless steel, for example, or coated on the inside with aluminum or another suitable material, while the valve disk and bellows are usually made of steel. The bellows, which can be expanded and compressed along its longitudinal axis within the range of the adjustment travel of the disk, seals the flow chamber airtight from the valve rod and the drive. Two main types of bellows are used. One is the diaphragm bellows and the other is the corrugated bellows, which is distinguished from the diaphragm bellows by the fact that it has no weld seams and is easier to clean, but has a smaller maximum stroke.

The valve according to the invention and the sealing element are described in more detail below by way of purely exemplary embodiments shown schematically in the drawings, Identical elements are marked with the same reference signs in the figures. The embodiments described are generally not shown to scale and are not to be understood as a limitation, wherein in detail:

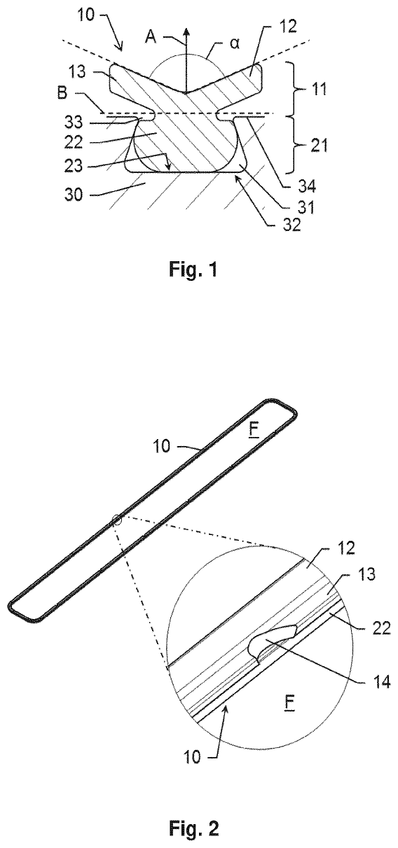

FIG. 1 shows a first embodiment of a sealing element according to the invention in cross-section;

FIG. 2 shows a further embodiment of a sealing element according to the invention in spatial representation;

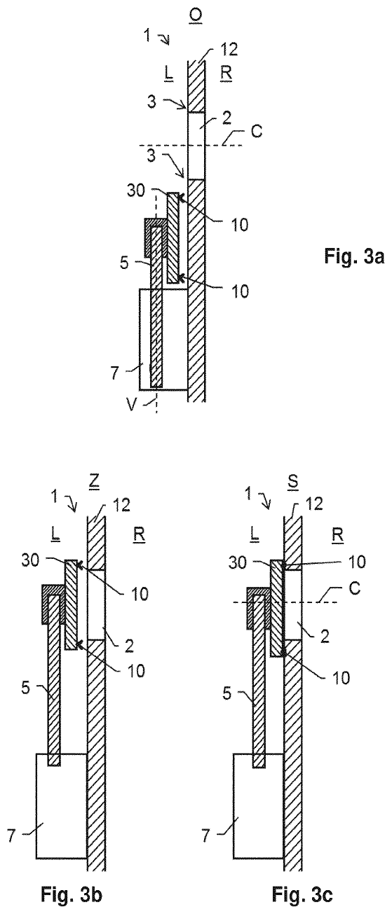

FIGS. 3a-c show an embodiment of a vacuum valve according to the invention having a valve closure according to the invention with such a sealing element according to the invention; and

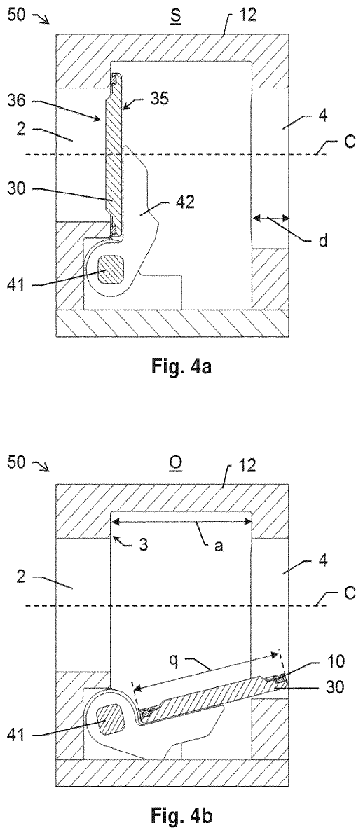

FIGS. 4a-b show an embodiment of a valve according to the invention closed and open.

FIG. 1 shows an embodiment of a sealing element 10 according to the invention, which is fastened in a groove 31 of a valve closure 30. The sealing element 10 has a sealing region 11 and a fastening region 21.

The fastening region 21 has a fastening body 22, which is designed to fasten the sealing element 10 to the valve closure 30. For this purpose, the fastening body 22 has an underside with a retaining surface 23, which is arranged and aligned opposite the sealing region. The retaining surface 23 is flat in this case. Furthermore, the fastening body 22 provides a defined width with respect to a direction parallel to a transverse axis B.

The groove 31 of the valve closure 30 has a groove bottom surface 32 which is flat and is aligned parallel to a surface of the valve closure 30, in particular parallel to the closing surface 34 of a closing side of the valve closure 30. The retaining surface 23 of the fastening body 22 lies, in particular plane-parallel, against the groove bottom surface 32. In this way, a defined alignment of the entire sealing element 10 relative to the valve closure 30 can be reliably provided. A contact pressure direction A defined by the shape of the sealing region 21 thus has a desired orientation relative to the closing surface 34, particularly in an open position of the valve closure.

The interaction of the two surfaces 23 and 32 can also effectively prevent the sealing element 10 from tilting or rotating.

As shown in this embodiment, the groove 31 has a trapezoidal cross-section.

A groove opening 33 of the groove 31 opposite the groove bottom surface 32 has a width that is smaller than the defined width of the fastening body 22. This ensures that the fastening body 22 remains permanently in the groove 31. The width of the groove opening 33 is correspondingly smaller than the width of the groove bottom.

The fastening region 21 and the sealing region 11 are designed to be contiguous and connected to each other. In particular, the sealing element 10 is formed in one piece. In one embodiment, a defined elasticity can be provided between the fastening region 21 and the sealing region 11 due to the shape. This allows the sealing region 11 to tilt against the valve seat when the valve is closed. This prevents shear forces between the seal and the valve seat and the associated generation of particles.

In the sealing region 11, the sealing element 10 has a sealing lip 12 and an aligning lip 13. The sealing lip 12 and the aligning lip 13 are aligned relative to each other in such a way that they enclose an opening angle o. This alignment also defines the Y-shape of the sealing element 10.

The sealing lip 12 is designed to provide the sealing of a valve opening of a valve by pressing the sealing lip 12 onto a sealing surface of the valve (in particular provided by the valve seat of the valve). The aligning lip 13 is designed at least for aligning the sealing region 11 relative to the sealing surface of the valve when it is brought into contact with the sealing surface.

The aligning lip 13 thus ensures that the sealing element 10 is pressed on in contact pressure direction A in particular. The contact pressure direction A can vary according to an inclination of the sealing region 11 relative to the fastening region 21. Tilting can be understood here as a joint tilting of the sealing lip 12 and the aligning lip 13 relative to the fastening body. The opening angle o can remain essentially unchanged.

FIG. 2 shows a spatial view of a further embodiment of a sealing element 10 according to the invention. The sealing element 10 is designed here as a closed sealing element 10, i.e. it is shaped in such a way that, for example, an edge area of a valve closure can be completely surrounded by it without interruption. The sealing element 10 thus comprises an inner surface F or encloses this inner surface F. The sealing element 10 can be understood in particular as an annular sealing element 10.

The sealing element 10 thus has a longitudinal extension, wherein the longitudinal extension here extends largely in a direction orthogonally to the transverse axis B and orthogonally to the contact pressure direction A.

The sealing element 10 has a plurality, here for example twelve, of venting notches 14 (recesses). These recesses 14 are provided along the aligning lip 13. FIG. 2 shows an enlarged section of the sealing element 10 from an area with such a recess 14,

The aligning lip 13 is aligned in the direction of the inner surface F enclosed by the sealing element 10, with the sealing lip 12 facing away from the inner surface F in the opposite direction.

The recesses 14 are designed in such a way that an intermediate space, which is created between the sealing surface, the sealing lip 12 and the aligning lip 13 when the sealing region, i.e. the sealing lip 12 and the aligning lip 13, is brought into contact with a sealing surface, remains accessible from the inner surface F through the recesses 14. The inner surface F is typically in the vacuum region when the valve is closed, i.e. in an in-contact state. This means that the intermediate space can be completely vented due to the prevailing vacuum.

In the embodiment shown, the recesses 14 are crescent-shaped. Alternatively, these recesses 14 can be realized by other shapes, such as slots or holes, in the aligning lip 13.

FIGS. 3a-c show an embodiment of a vacuum valve 1 according to the invention with a valve closure 30 according to the invention with a sealing element 10 according to the invention.

The vacuum valve 1 is designed as a vacuum transfer valve 1 and is shown in different opening states.

The vacuum valve 1 has a rectangular, plate-shaped valve closure 30 (valve disk), which has a sealing element 10 for gas-tight closure of a valve opening 2. The opening 2 has a cross-section corresponding to the valve closure 30 and is formed in a wall of the valve housing 12. This wall can, for example, be the wall of a vacuum process chamber. The opening 2 is surrounded by a valve seat, which in turn provides a sealing surface 3 corresponding to the sealing element 10 of the valve closure 30. The sealing element 10 of the valve closure 30 revolves around the valve closure 30. In a closed position S (FIG. 3c), the seal is pressed between the valve closure 30 and the sealing surface 3.

The opening 2 connects a first gas region L, which is located to the left of the wall 12, with a second gas region R to the right of the wall 12. The wall 12 is formed, for example, by a chamber wall of a vacuum chamber. The vacuum valve 1 is then formed by interaction between the chamber wall 12 and the valve closure 30.

It is understood that the valve seat together with the sealing surface 3 can alternatively be designed as a valve component structurally fixed to the valve 1 and can, for example, be arranged, e.g. screwed, to a chamber opening.

As shown here, the valve closure 30 can be arranged on an adjustment arm 5, which here is rod-shaped, for example, and extends along a geometric adjustment axis V. The adjustment arm 5 is mechanically coupled to a drive unit 7, by means of which the valve closure 30 in the first gas region L to the left of the wall 12 can be adjusted between an open position O (FIG. 3a) via an intermediate position Z (FIG. 3b) into a closed position S (FIG. 3c) by adjusting the adjustment arm 5 by means of the drive unit 7.

In the open position O, the valve closure 30 is located outside a projection area of the opening 2 and releases it completely, as shown in FIG. 3a.

By linear adjustment of the valve closure 30 in the axial direction in a plane parallel to or coaxial with the adjustment axis V and parallel to the wall 12, the valve closure 30 can be adjusted from the open position O to the intermediate position Z by means of the drive unit 7.

In this intermediate position Z (FIG. 3b), the sealing element 10 of the valve closure 30 is located at a distance opposite the sealing surface 3 of the valve seat surrounding the opening 2.

By adjusting in the direction of the opening axis C defined by the opening 2 (here: transverse to the adjustment axis V), e.g. perpendicular to the wall 12 and the valve seat, the valve closure 30 can be adjusted from the intermediate position Z to the closed position S (FIG. 3c).

In the closed position S, the valve disk 30 closes the opening 2 in a gas-tight manner and separates the first gas region L from the second gas region R in a gas-tight manner.

The vacuum valve is opened and closed by means of the drive unit 7, in this case by an L-shaped movement in two directions V and C of the valve closure 30, e.g. perpendicular to each other. The valve shown is therefore also called an L-type valve.

A transfer valve 1 as shown is typically used to seal a process volume (vacuum chamber) and to load and unload the volume, Frequent changes between the open position O and the closed position S are the rule in such an application.

The valve closure 30 has a groove in which a fastening body of the sealing element 10 is arranged. This holds the sealing element 10 on the valve closure 30. The sealing element has two lips, an outer sealing lip and an inner aligning lip, which are arranged at an angle to each other. The fastening body has a retaining surface and the groove has a groove bottom surface and these are designed in such a way that their interaction prevents the sealing element 10 from tilting relative to the valve closure 30.

The aligning lip can be designed according to the embodiment shown in FIG. 2 and have corresponding recesses.

FIGS. 4a and 4b show an embodiment of a valve 50 according to the invention closed, i.e. in a closed position S, and open, i.e. in an open position O. The valve 50 shown here is designed as a vacuum valve, in particular for closing and opening a valve opening and for transferring a substrate.

The valve 50 has a valve housing 12 with a first valve opening 2 and an opposing second valve opening 4, wherein the first valve opening 2 defines an opening axis C and the opening axis C extends through the first valve opening 2 and the second valve opening 4. In addition, a valve seat is provided, which extends around the first valve opening 2 and has a first sealing surface 3 extending around the first valve opening 2. A valve closure 30, in particular a valve disk, is arranged in particular for essentially gas-tight closure of the valve opening 2.

The valve 50 thus has two valve openings, only one of which can be closed with the valve closure 30 in this embodiment. Such a valve is used in particular as a transfer valve, as described above, i.e. the valve is designed in such a way that in an open state a substrate can be fed linearly through both valve openings.

Furthermore, the valve closure 30 is provided on its coupling side 35 with a coupling for coupling to a drive unit. The drive unit here has an arm 42 that can be pivoted about the axis of rotation 41 by means of the drive unit, wherein the arm 42 is coupled to the coupling of the valve closure 30. The axis of rotation can, for example, be driven, i.e. rotated, by means of a pneumatic or mechatronic drive (not shown). The valve may have a plurality of such arms, which may be coupled to the valve closure along its extension and may be connected and adjusted together with the common axis of rotation (shaft). The axis of rotation can penetrate the valve housing and be connected to the drive outside the valve housing.

The drive unit coupled to the valve closure 30 is thus adapted to provide a folding movement of the valve closure 30 about the axis of rotation 41, which is oriented orthogonally relative to the opening axis C. The folding movement can take place in such a way that the valve closure 30 can be moved from an open position O (FIG. 4b), in which the valve closure 30 opens the valve opening 2 to the maximum, into a closed position S (FIG. 4a), in which there is a sealing contact between the valve closure 30 and the valve seat 3 by means of the interposed sealing element 10 and the valve opening 2 is thus closed in a gas-tight manner, and back again.

The valve 50 is designed such that, in the open position O, at least part of the valve closure 30 protrudes into the second valve opening 4. As a result, the valve can be designed with a significantly reduced installation dimension compared to such valves of the prior art. In conventional valves of the prior art, the valve closure is completely located between the two valve openings in the open position.

In particular, the valve 50 is designed such that an opening cross-section of the second valve opening 4 in the open position O is reduced (compared to the closed position) by the valve closure 30 engaging in the opening 4, but is still at least as large as the opening cross-section of the first valve opening 2.

The second valve opening 4 has a through-flow region provided by the valve housing 12, in particular by a thickness d of the housing wall, in the direction of the opening axis C and the valve closure 30 is at least partially present in the through-flow region in the open position O.

In addition, a distance a between the first valve opening 2 and the second valve opening 4 is smaller than a spatial extension of the valve closure 30 corresponding to its transverse extension q. The distance a between the first valve opening 2 and the second valve opening 4 is defined here by an inner wall of the valve housing 12 bounding the valve openings.

In the embodiment shown, the valve 50 has a valve closure 30 having a circumferential sealing element 10 which, as described in connection with FIG. 2, has Y-shaped lips, an aligning lip and a sealing lip. The combination with such a sealing element provides an improved sealing effect, in particular due to the contact pressure still available due to the adapted and specific drive concept, in particular the lower contact pressure compared to drives of the prior art.

When pressed, the sealing lip provides a wider contact surface with the valve seat. In addition, it has a comparatively larger tolerance range with regard to maintaining the sealing effect, as contact between the elastic sealing lip and the valve seat can still be maintained even if the distance between the valve closure 30 and the valve seat 3 is (slightly) increased-for example due to a large pressure difference,

Alternatively, the valve closure can have a typical sealing ring, e.g. O-ring, or a vulcanized sealing material.

It should be understood that the figures shown are only schematic representations of possible embodiments. The various approaches can also be combined with each other and with devices and methods of the prior art.

1. A sealing element for a valve closure and/or a valve seat of a valve, comprising:
a fastening region with a fastening body, which is designed for fastening the sealing element to the valve closure and/or the valve seat; and
a sealing region for providing a seal of a valve opening of the valve: wherein the fastening region and the sealing region are connected to one another,
wherein:
the sealing element has a sealing lip and an aligning lip in the sealing region, wherein the sealing lip and the aligning lip are aligned relative to one another in such a way that they enclose an opening angle, wherein:
the sealing lip is designed to provide the sealing of the valve opening of the valve; and
the aligning lip is designed to align the sealing region relative to a sealing surface when brought into contact with the sealing surface; and
the fastening body has at least one retaining surface on an underside opposite the sealing region.

2. The sealing element according to claim 1,
wherein:
the sealing lip and the aligning lip enclose the opening angle from a range between 90° and 160°.

3. The sealing element according to claim 1, wherein:
the retaining surface is aligned parallel to a transverse axis and the transverse axis is oriented orthogonally to a contact pressure direction defined by the opening angle, wherein the retaining surface is of flat design, or
the retaining surface is aligned transversely to the transverse axis, or
the sealing element has at least one further retaining surface.

4. The sealing element according to claim 1, wherein:
the fastening body has a retaining element, wherein the retaining element provides the retaining surface, wherein the retaining element is aligned in the opposite direction relative to the contact pressure direction A, wherein the retaining element is designed as a pin, web, wedge or mandrel.

5. The sealing element according to claim 1, wherein:
the sealing element has a longitudinal extension, wherein the longitudinal extension extends in a direction orthogonally to the transverse axis and orthogonally to the contact pressure direction.

6. The sealing element according to claim 5, wherein:
the sealing element is designed as a closed sealing element, as a circumferential seal or as a ring.

7. The sealing element according to claim 1, wherein:
the aligning lip has at least one recess, plurality of recesses, wherein the at least one recess is designed in such a way that an intermediate space, which is created between the sealing surface, the sealing lip and the aligning lip when the sealing region is brought into contact with the sealing surface, remains accessible through the at least one recess.

8. The sealing element according to claim 7, wherein:
the at least one recess is shaped as a notch or perforation.

9. A valve closure, for a vacuum valve, for regulating a volume or mass flow and/or for closing and opening a valve opening, having
a coupling side comprising a coupling which is designed for coupling to a drive unit of the valve, and
a rear closing side relative to the coupling side with a seal that corresponds to a sealing surface of a valve seat of the valve,
wherein:
the valve closure has a retaining region on the closing side,
the seal is designed as a sealing element according to one of the preceding claims, and
the fastening body of the fastening region is connected to the retaining region.

10. The valve closure according to claim 9, wherein:
the fastening body of the fastening region is connected to the retaining region by means of vulcanization.

11. The valve closure according to claim 9, wherein:
the retaining region has a groove and the fastening body of the fastening region is located in the groove.

12. The valve closure according to claim 11, wherein:
the groove is formed circumferentially in an edge region of the valve closure.

13. The valve closure according to claim 11 wherein:
the groove has a groove bottom surface which is designed to correspond to the retaining surface of the fastening body.

14. The valve closure according to claim 13, wherein:
the groove has a trapezoidal cross-section, wherein the groove bottom surface is aligned parallel to a surface of the closing side.

15. The valve closure according to claim 13,
wherein:
the retaining surface of the fastening body rests against the groove bottom surface.

16. The valve closure according to claim 11,
wherein:
a groove opening of the groove has a width which is smaller than a width of the fastening body, wherein the groove opening is opposite the groove bottom surface.

17. A valve in particular wherein the valve is a vacuum valve, for regulating a volume or mass flow and/or for closing and opening a valve opening, having
a valve seat which has the valve opening defining an opening axis and a first sealing surface surrounding the valve opening,
a valve closure, for regulating the volume or mass flow and/or for substantially gas-tight closure of the valve opening with a second sealing surface corresponding to the first sealing surface, and
a drive unit coupled to the valve closure, which is adapted to provide a movement of the valve closure in such a way that the valve closure is moved from
an open position, in which the valve closure at least partially releases the valve opening, into
a closed position in which there is a sealing contact between the first sealing surface and the second sealing surface by means of a seal present therebetween and the valve opening is thereby closed in a gas-tight manner,
and is adjustable back again,
wherein:
the valve has a sealing element according to claim 1 and the sealing element provides the seal.

18. The valve according to claim 17,
wherein:
the valve closure is designed according to claim 9 and the second sealing surface has the retaining region.

19. The valve according to claim 17,
wherein:
the first sealing surface has the sealing element.

20. The valve according to claim 17,
wherein:
the first sealing surface has a retaining region and the fastening body of the fastening region is connected to the retaining region, wherein the fastening body of the fastening region is connected to the retaining region by means of vulcanization, or the retaining region of the first sealing surface has a groove and the fastening body of the fastening region is located in the groove.

21. A valve, wherein the valve is a vacuum valve, for regulating a volume or mass flow and/or for closing and opening a first valve opening, having
a valve housing with the first valve opening and an opposing second valve opening, wherein the first valve opening defines an opening axis and the opening axis extends through the first and the second valve opening,
a valve seat that extends around the first valve opening and has a first sealing surface extending around the first valve opening,
a valve closure, for regulating the volume or mass flow and/or for substantially gas-tight closure of the valve opening, and
a drive unit coupled to the valve closure, which is adapted to provide a folding movement of the valve closure about an axis of rotation oriented orthogonally relative to the opening axis in such a way that the valve closure is moved from
an open position, in which the valve closure releases the first valve opening to the maximum, into
a closed position, in which there is a sealing contact between the valve closure and the valve seat and the first valve opening is thereby closed in a gas-tight manner,
and is adjustable back again,
wherein:
in the open position, at least a part of the valve closure projects into the second valve opening.

22. The valve according to claim 21, wherein:
the second valve opening defines a second cross-sectional region which is larger than a first cross-sectional region of the first valve opening, wherein the first and the second cross-sectional regions are oriented orthogonally to the opening axis.

23. The valve according to claim 21,
wherein:
the second valve opening has a through-flow region provided by the valve housing, by a thickness of the housing wall, in the direction of the opening axis, and the valve closure is at least partially present in the through-flow region in the open position.

24. The valve according to claim 21, wherein:
the first valve opening , the second valve opening and the valve closure each have a longitudinal extension and a transverse extension and the respective transverse extension is smaller than the respective longitudinal extension, wherein
the longitudinal extension and the transverse extension of the first valve opening are oriented orthogonally to the opening axis and orthogonally relative to one another, and/or
the longitudinal extension and the transverse extension of the valve closure—in the closed position—are oriented orthogonally to the opening axis and orthogonally relative to each other.

25. The valve according to claim 24,
wherein:
a distance between the first valve opening and the second valve opening is smaller than a spatial extension of the valve closure corresponding to its transverse extension, wherein the distance between the first valve opening and the second valve opening is defined by an inner wall of the valve housing bounding the valve openings.

26. The valve according to claim 24,
wherein:
the longitudinal extension of the first valve opening is smaller than the longitudinal extension of the valve closure, and/or
the longitudinal extension of the second valve opening is greater than the longitudinal extension of the valve closure.

27. The valve according to claim 21, wherein:
the valve closure has a coupling side with a coupling for coupling to the drive unit,
the drive unit has an arm which can be pivoted about the axis of rotation by means of the drive unit, and
the arm is coupled to the coupling.

28. The valve according to claim 21, wherein:
the valve closure is designed according to claim 9.

29. The valve according to claim 21, wherein:
the first sealing surface comprises a sealing element according to claim 1.

30. The valve according to claim 29,
wherein:
the first sealing surface has a retaining region, and the fastening body of the fastening region is connected to the retaining region, wherein the fastening body of the fastening region is connected to the retaining region by means of vulcanization, or the retaining region of the first sealing surface has a groove and the fastening body of the fastening region is located in the groove.
